(19) United States
(12) Patent Application Publication
(10) Pub. No.: US 2015/0036279 A1
(43) Pub. Date: Feb. 5, 2015

(54) PORTABLE SYSTEM CONFIGURED TO BE DEPLOYED IN A NETWORK

(71) Applicant: TABLET IFE LLC, New York, NY (US)

(72) Inventors: Tyler Erdman, New York, NY (US); Dean DiPietro, Brooklyn, NY (US); Pepin Gelardi, Brooklyn, NY (US); Ted Ullrich, Brooklyn, NY (US)

(21) Appl. No.: 14/446,963

(22) Filed: Jul. 30, 2014

Related U.S. Application Data
(60) Provisional application No. 61/860,084, filed on Jul. 30, 2013.

(51) Int. Cl. H05K 7/20; H05K 7/14

(52) U.S. Cl. CPC H05K 7/20754; H05K 7/20718; H05K 7/20836; H05K 7/14
USPC 361/679.31; 361/679.46; 361/679.48; 361/679.54; 361/679.47

(57) ABSTRACT

A portable system that includes a portable housing having a section for reception of portable wireless computing devices such as tablets, and components to provide recharging capability and information to the portable wireless devices.

### CROSS REFERENCE TO RELATED APPLICATION AND CLAIM OF PRIORITY

The present application is a non-provisional application of U.S. Provisional Application Ser. No. 61/860,084, filed Jul. 30, 2013, having the same title as the present application. The entire contents of the provisional application are incorporated by reference.

### FIELD OF INVENTION

The present invention relates to information systems and in particular a portable system configured to be deployed in a computer network.

### BACKGROUND AND SUMMARY OF THE INVENTION

U.S. Pat. No. 6,438,577 ('577 patent) discloses a portable network including a server and a plurality of computing devices assembled in a briefcase. Specifically, the '577 patent discloses a briefcase having exterior walls and interior walls. The interior walls define a space for receiving the computing devices, while the space between the interior walls and the exterior walls are used for housing other components such as the battery, the power supply, the hard disk, the server and other components.

As is well known, electronic components such as power supplies, processors, and computing devices generate heat during operation. For example, a portable computer may heat up while charging, and the power supply that supplies the charge to the portable computer also heats up while charging the battery of the portable computer. The heat so generated must be dissipated. Otherwise, malfunction may occur. Typically, the heat so generated is released to the ambient environment as air usually takes the heat away from the heated component. However, the configuration proposed by the '577 patent packs all components tightly next to one another, which restricts the circulation of air. Furthermore, in the configuration shown by the '577 patent the region defined for receiving the computing devices is separated from the region defined for receiving the components of the server by interior walls. Thus, heat cannot flow easily from a high temperature region to a low temperature region in order to escape. In short, the arrangement proposed by the '577 patent creates heat transfer barriers and heat traps, which may adversely affect the operation of the components.

On the other hand, in a system according to the present invention, a housing is provided to allow for the free flow of air to avoid internal barriers to the transfer of heat from a high temperature region to a low temperature region in order to prevent the generation of heat traps that may cause malfunction.

In the first embodiment, an open internal frame work is used to support panels of the housing and the components. The internal frame work allows for the circulation of air among the components of the system and even the computing devices, and the air so circulated can be cooled by, for example, heat dissipation from the external panels of the housing.

In the second embodiment, the housing has an open interior as well allowing for circulation of the air among the components and the computing devices. In the second embodiment, the housing structure itself is configured to have a region or regions for heat spreading by direct thermal connection to the heat generating component(s).

A system according to the present invention includes a portable housing having a section for receiving a plurality of computing devices. The housing defines a space for a plurality of components that are configured to provide power and information to the computing devices, the components including at least a power supply, a processor, and a router (preferably wireless). The housing is configured to allow for circulation of air among the components and the computing devices received in the section for receiving the plurality of computing devices. In a system according to the present invention the components further include a charger circuit, a non-volatile memory, input/output connectors, and at least one rechargeable battery.

The housing may include a fascia panel having a plurality of elongated slots each configured to receive a respective computing device and to guide the computing device so received into the section for receiving the plurality of computing devices. The fascia panel is preferably positioned opposite a support wall that supports a plurality of connectors, each connector being configured for connection to a respective computing device. Each slot in the fascia plate may be associated with a visual indicator.

In a system according to the present invention, each connector may be mounted on the support wall with a respective connector support, which connector support positions and orients its associated connector for connection to a power input connector of a respective computing device.

Each connector may be associated with a connector assembly and each connector assembly may be associated with a respective releasable stop assembly.

Each releasable stop assembly may include a movable stop which when pushed toward the support wall by a computing device will move until reaching a stop position to prevent further advancement of the computing device.

Each releasable stop assembly may be configured to release the stop when the stop is pushed toward the support wall after it has been locked.

Each stop may be spring loaded, or magnetically locked and releasable.

Each stop may be associated with a respective lock assembly. Each lock assembly may include a rotatable catch that cooperates with a latch to prevent the stop from moving toward the support wall.

Each lock assembly may be configured to prevent mismounting of a computing device.

In the first embodiment, the housing includes an internal open framework supporting a plurality of panels that define the portable housing.

A system according to the second embodiment includes a portable housing having at least one metallic tray. The portable housing houses therein a plurality of components that are configured to provide power and information to a plurality of computing devices, the components including at least a power supply, a processor, and a router (preferably wireless), wherein at least one of the components is thermally coupled to the metallic tray.

The housing of the second embodiment may further include a fascia panel having a plurality of elongated slots each configured to receive a respective computing device and to guide the computing device so received into a section for receiving the plurality of computing devices inside the housing, the fascia panel being positioned opposite a support wall that supports a plurality of connectors, each connector being configured for connection to a respective computing device. Each slot in the fascia plate may be associated with a visual indicator.

Preferably, a system according to the second embodiment includes another metallic tray arranged opposite the metallic tray. At least another one of the components may be coupled to the another metallic tray. The metallic tray and the another metallic tray are preferably arranged on opposite sides of the section for receiving the computing devices. The metallic trays may have identical exterior appearances.

The metallic tray (or trays) may include a plurality of vent holes allowing air to pass from interior of the housing to the exterior of the housing. An electric fan may be installed adjacent the vent holes.

Preferably, the metallic tray is comprised of aluminum as it is visually pleasing, is light weight, and it is a good conductor of heat.

Other than its housing, the second embodiment would includes the same internal features such as the connector assemblies, the stop assemblies, the lock assemblies, and the same components as those in the first embodiment.

Other features and advantages of the present invention will become apparent from the following description of the invention which refers to the accompanying drawings.

### BRIEF DESCRIPTION OF THE FIGURES

FIG. 1 illustrates components of a system according to the present invention deployed in a network.

FIG. 2A is a right isometric view of a system according to the present invention.

FIG. 2B is a right isometric view of a system according to the present invention with its shutter removed from view to show wireless devices stored therein.

FIG. 2C is a left isometric view of a system according to the present invention with its shutter removed from view.

FIG. 3A illustrates a system according to the present invention as shown in FIG. 2B without the exterior panels.

FIG. 3B illustrates a system according to the present invention as shown in FIG. 3A without at least some of the stored devices.

FIG. 3C illustrates a front plan view of a fascia plate in a system according to the present invention.

FIG. 3D illustrates a system according to the present invention as illustrated in FIG. 3B without some of the batteries and a cage supporting the batteries.

FIG. 3E illustrates a system according to the present invention as illustrated in FIG. 3D without a support plate.

FIG. 3F illustrates a top plan view of a system according to the present invention as illustrated in FIG. 3E, without top braces.

FIG. 3G illustrates a system according to the present invention as illustrated in FIG. 3E without the stored device.

FIG. 3H illustrates a system according to the present invention as illustrated in FIG. 3E without the fascia plate.

FIG. 4A illustrates a connector assembly.

FIG. 4B illustrates the operation of a connector assembly in one state.

FIG. 4C illustrates the operation of a connector assembly in another state.

FIG. 4D illustrates the operation of a connector assembly when a device is improperly loaded into a system according to the preferred embodiment of the present invention.

FIG. 5A is an isometric view of a system according to the second embodiment of the present invention.

FIG. 5B is a front plant view with portions of the side trays of the housing removed showing the arrangement of the components inside the housing.

FIG. 5C illustrates the interior of one of the trays of the housing of the second embodiment and some of the components of the system mounted therein.

FIG. 5D illustrates the processor mounted to the interior of one of the side trays of the housing along with a heatsink.

FIG. 5E illustrates a back plan view of a system according to the second embodiment of the present invention.

FIG. 5F illustrates a front plan view of a system according to the second embodiment of the present invention.

FIG. 5G illustrates a top plan view of a system according to the second embodiment of the present invention.

FIG. 5H illustrates a side plant view of a system according to the second embodiment with an optional trim.

### DETAILED DESCRIPTION

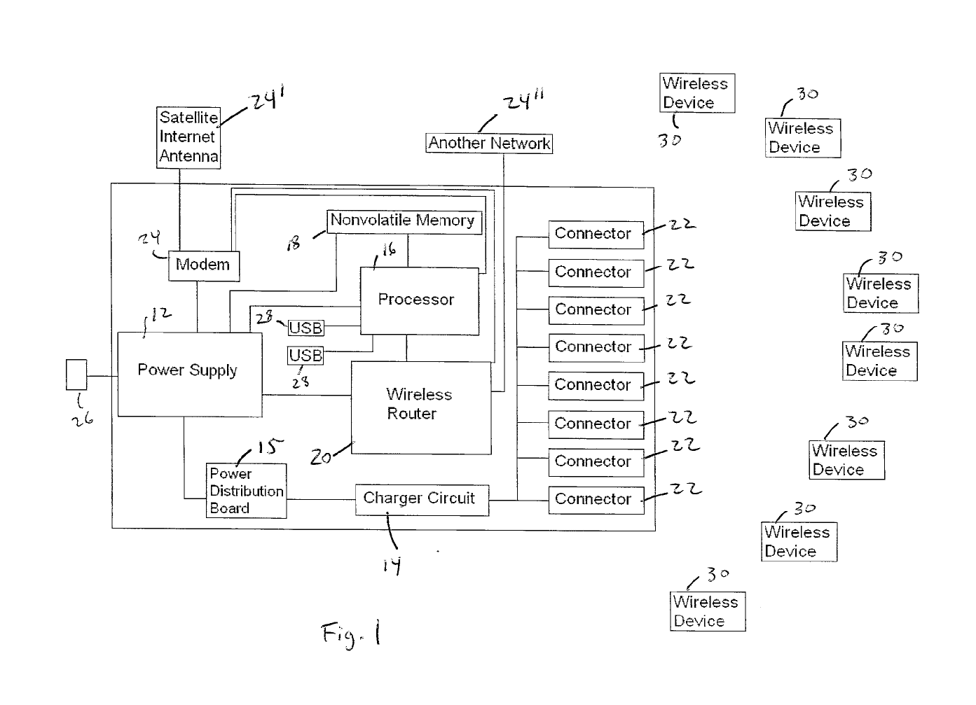

Referring to FIG. 1, a system 10 according to the present invention includes a power supply 12, a charger circuit 14, a processor 16, a non-volatile memory 18, a wireless router 20, a plurality of connectors 22, and preferably a modem 24, all residing within a common, portable housing.

Power supply 12 is configured to receive power from an AC line source 26 via an ordinary and conventional plug, and includes one or more power converters to condition the input power from the line source 26 to a suitable power input for the other devices within system 10. Power supply 12 may also include one or more batteries. The batteries are connected to a power distribution board 15.

Power supply 12 supplies power at the appropriate voltage and current level to memory 18, processor 16, wireless router 20, charger circuit 14 and modem 24. It should be noted that batteries in power supply 12 supply power to charger circuit 14 in the event power from AC line source 26 is unavailable. Between power supply 12 and charging circuit 14 is a power distribution board 15 that connects to one of the outputs from power supply 12 and the batteries. Board 15 when receiving power from power supply 12 will route it directly to charging circuit 14 for the computing devices 30 (e.g. iPads) while also charging the batteries. Without external power the output from the batteries are routed to charging circuit 14.

Modem 24, when available, can be connected to a publicly accessible network (e.g. Internet). In one preferred embodiment, modem 24 may be connected to an antenna 24′ which is configured to connect modem 24 to a satellite for satellite Internet connection. GPS related information may be obtained via the satellite connection. Moreover, wireless router 20 may be configured for connection to another, local computer network 24″. For example, when deployed in an aircraft having a resident local computer network 24″ with Internet connection capability, router 20 may connected to network 24″. System 10 may be further provided with other input/output connectors 28 (e.g. USB connectors) for connection to cameras and other sources of electronic information and data.

Non-volatile memory 18 may be a hard drive, a solid-state electronic memory storage device, or any other information storage device which can be loaded or is preloaded with computer readable files.

For example, memory 18 may be loaded with moving pictures in digital format or games. In addition, maps or other information may be loaded into memory 18.

Processor 16 may be a conventional CPU suitable for service in the capacity of a server to provide processing service for a plurality of client devices.

Wireless router 20 is configured for short-range (e.g. less than 30 meters) wireless transmission of electronic information preferably in a digital format.

Charger circuit 14 is connected to a plurality of power connectors 22 residing within system 10. Each power connector 22 is configured to connect to the power input receptacle of a mobile computing device such as a tablet computer. Once a connector 22 is electrically connected to a power input connector of a mobile computing device, charger circuit 14 supplies power to the connected mobile device in order to recharge the on-board battery thereof. In the preferred embodiment, mobile computing devices capable of connection to connectors 22 are wireless computing devices 30 such as iPads® or the like devices.

In operation, a wireless device 30 may request a file (e.g. a movie or a game) from system 10. The request so made is received by wireless router 20, passed on to processor 16, which then retrieves the requested file from memory 18 and sends (e.g. streams) the requested file via wireless router 20 to the requesting wireless device 30. A wireless device 30 may also access the Internet through system 10 preferably the same way a client computer can access the Internet via a server in a network.

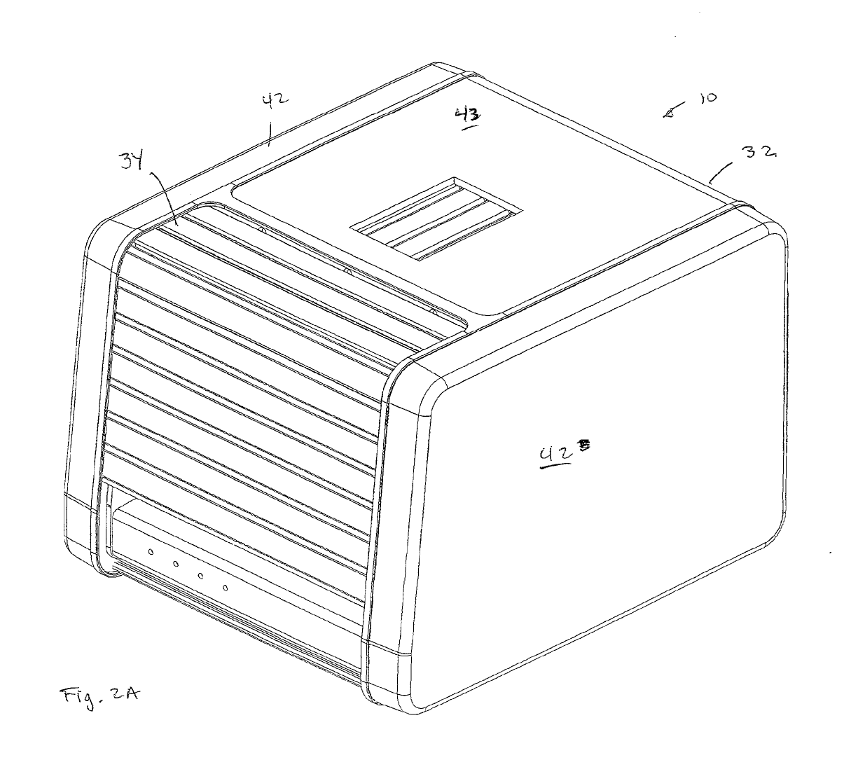

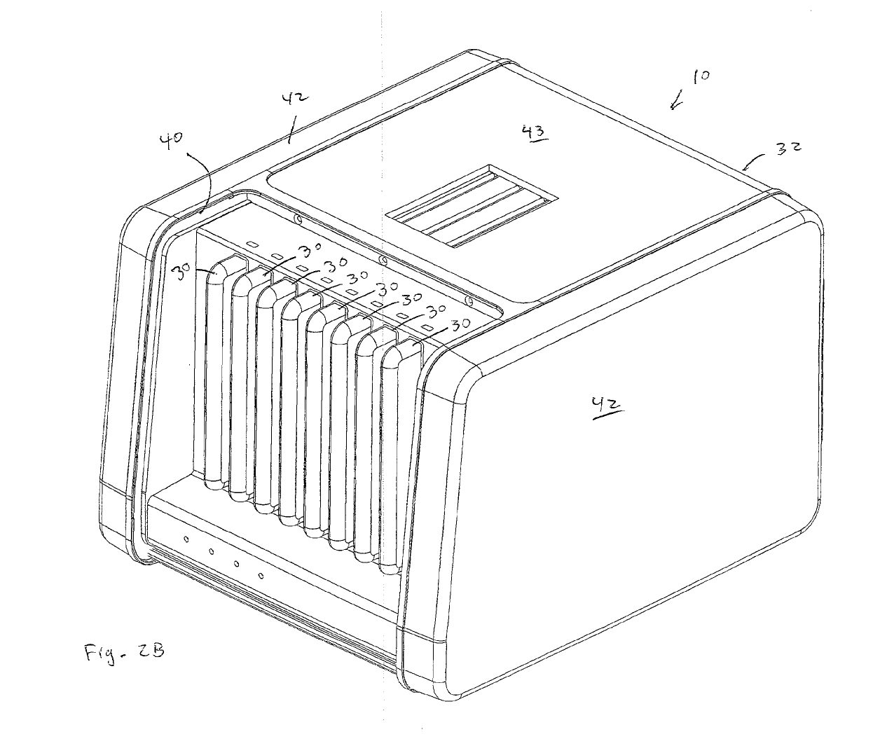

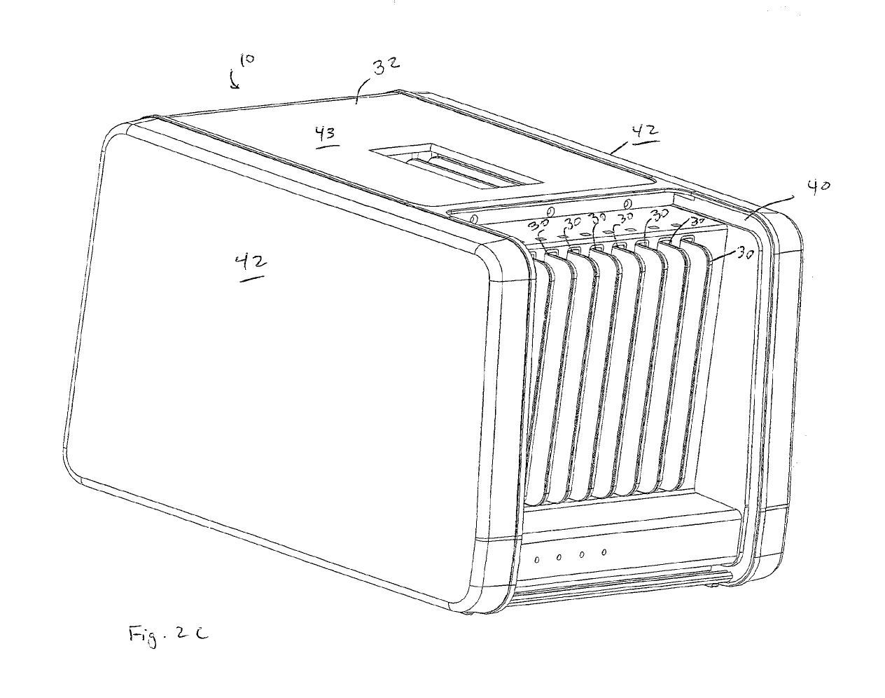

Referring to FIG. 2A, system 10 may be realized in a portable housing 32. Housing 32 may include a storage section for receiving a plurality of wireless devices 30. Housing 32 may include a protective lid or the like to enclose wireless devices 30 once devices 30 are stored within housing 32. The lid may be in the form of a metal or plastic rollable shutter 34 with a grip residing at or near a terminal edge thereof. Shutter 34 may be rolled into a compartment provided with the housing 32.

Referring to FIGS. 2B and 2C, shutter 34 includes opposite, parallel edges each received in a respective guiding recess 40 defined in housing 32. To enclose the storage section a user may pull shutter 34 to roll out shutter 34 out of its compartment. Guiding recesses 40 direct shutter 34 to close off the storage section and prevent access to devices 30 residing therein.

Note that a handle may be integrated with housing 32 to render system 10 easily portable. Alternatively, system 10 may be carried in a suitcase or the like portable apparatus.

Housing 32 may be constructed with a plurality of exterior side panels 42 and at least one top panel 43, the panels 42, 43 being supported by an interior frame. The interior frame is an open frame work.

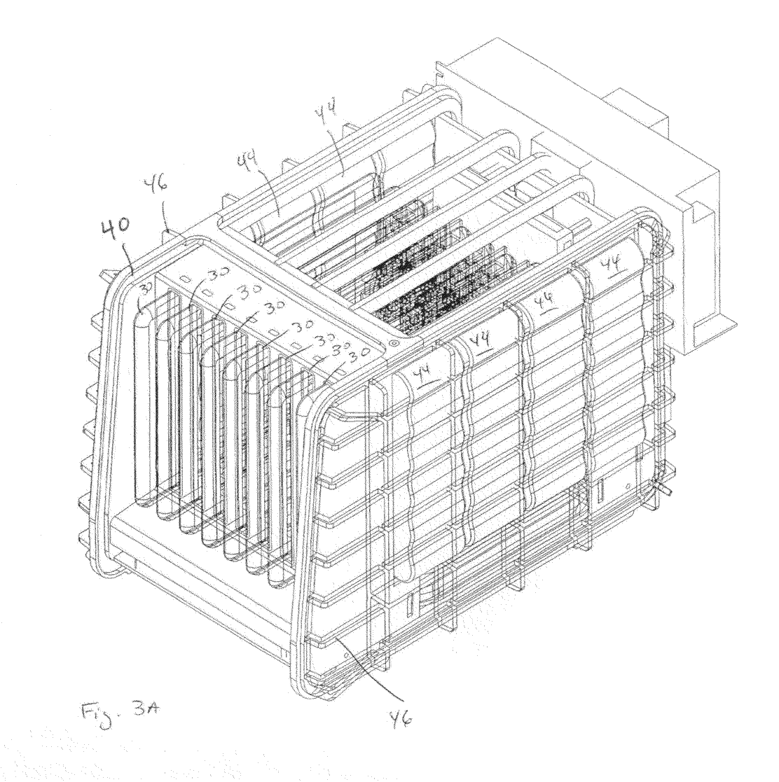

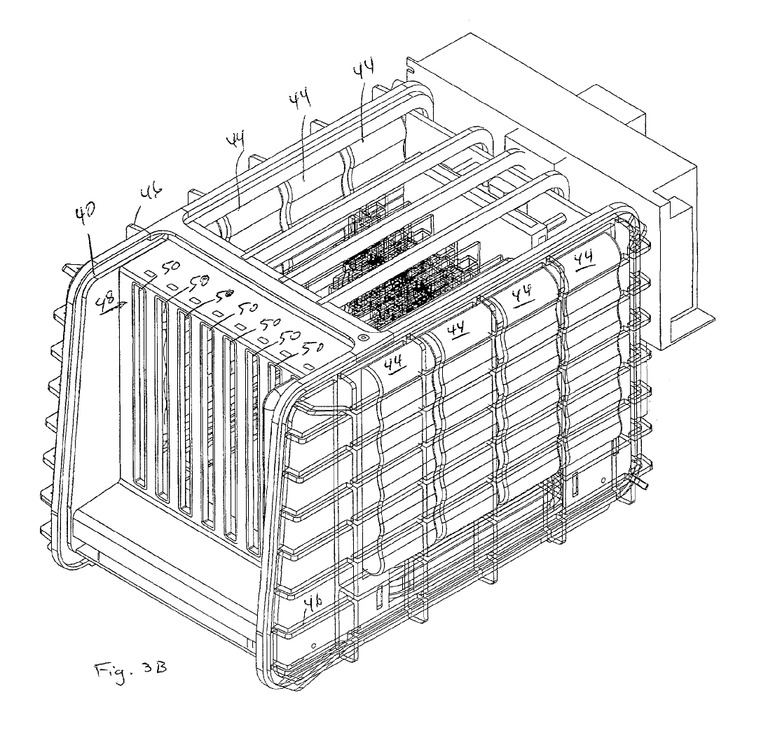

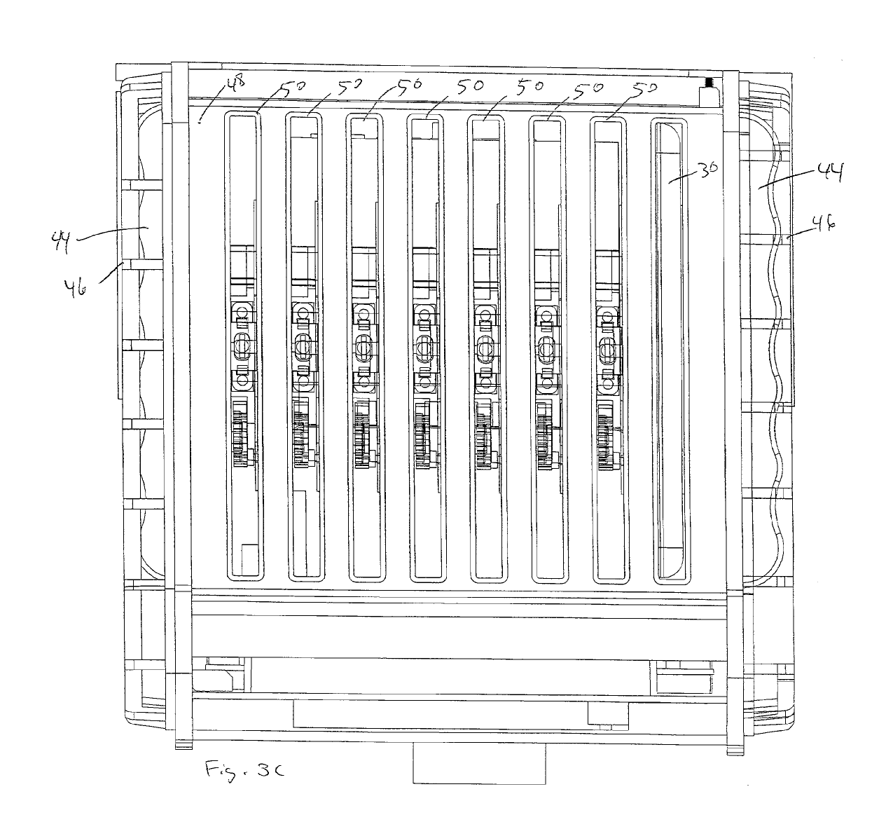

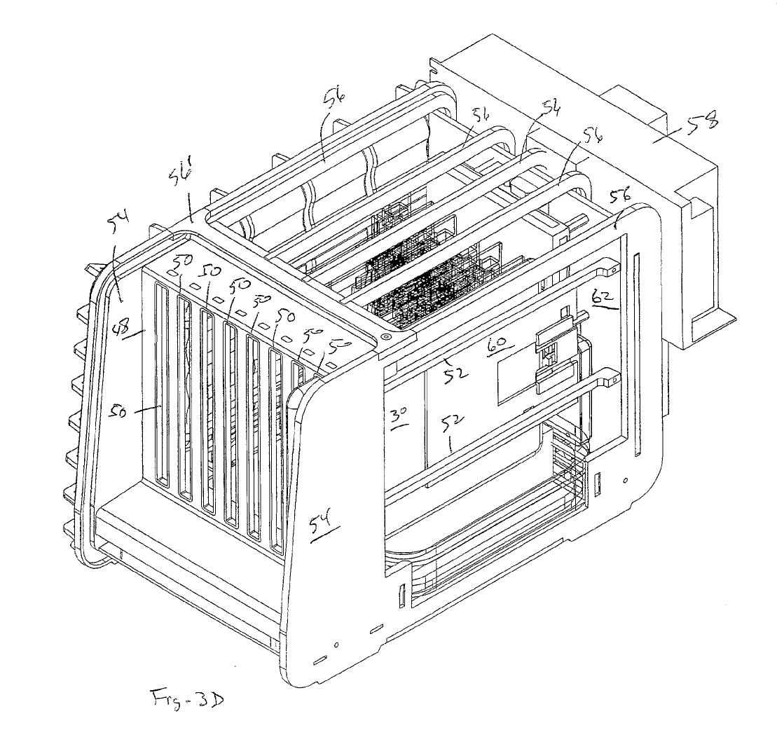

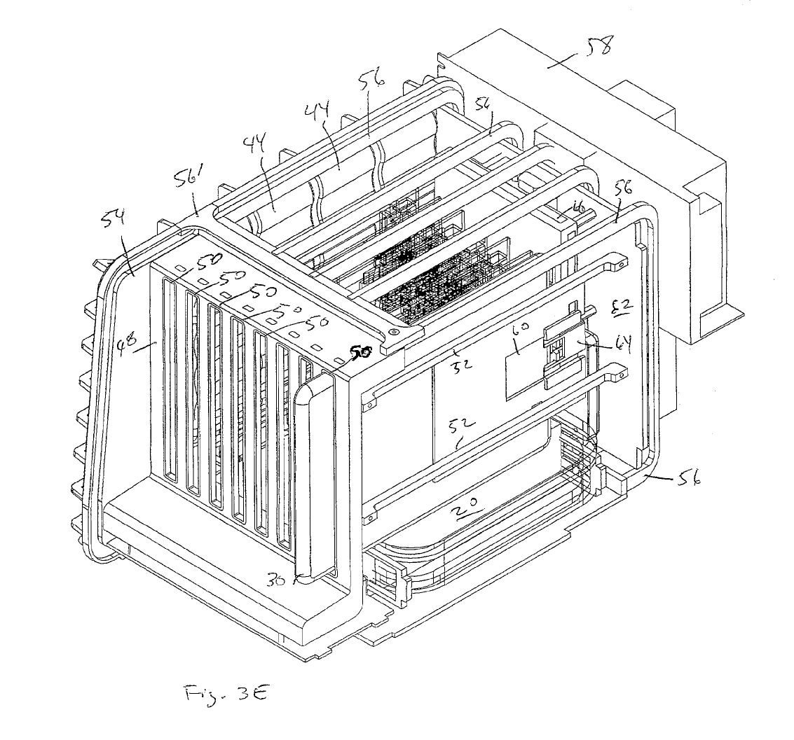

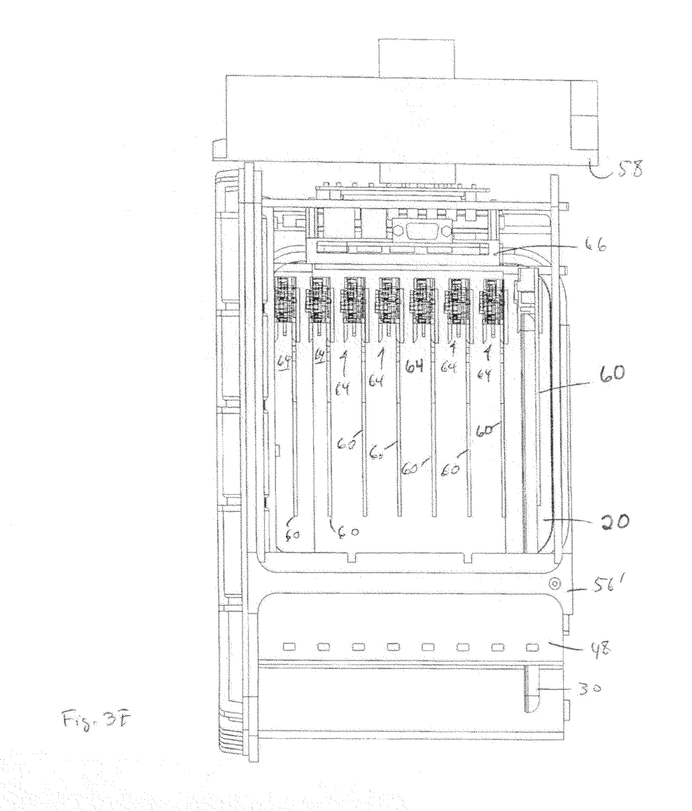

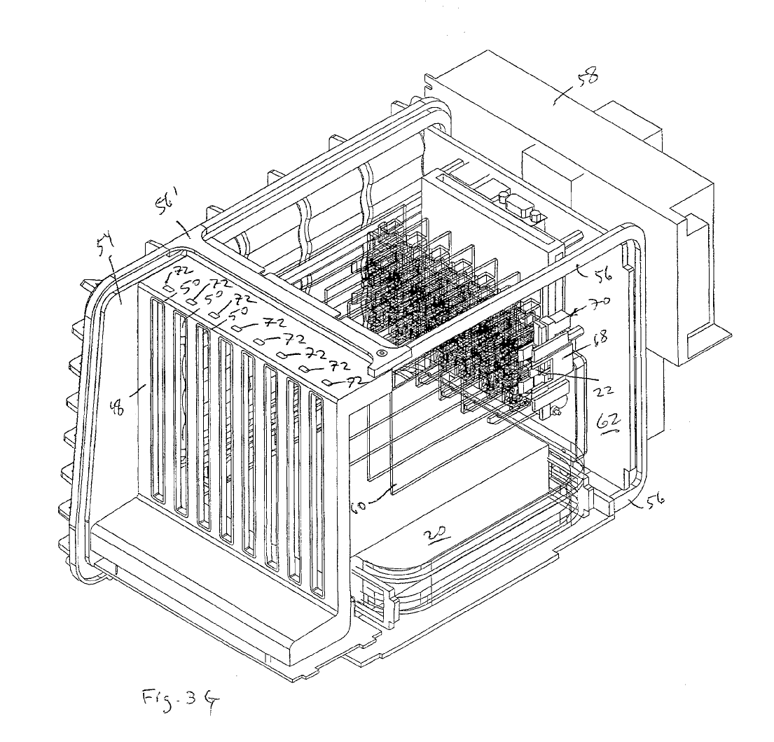

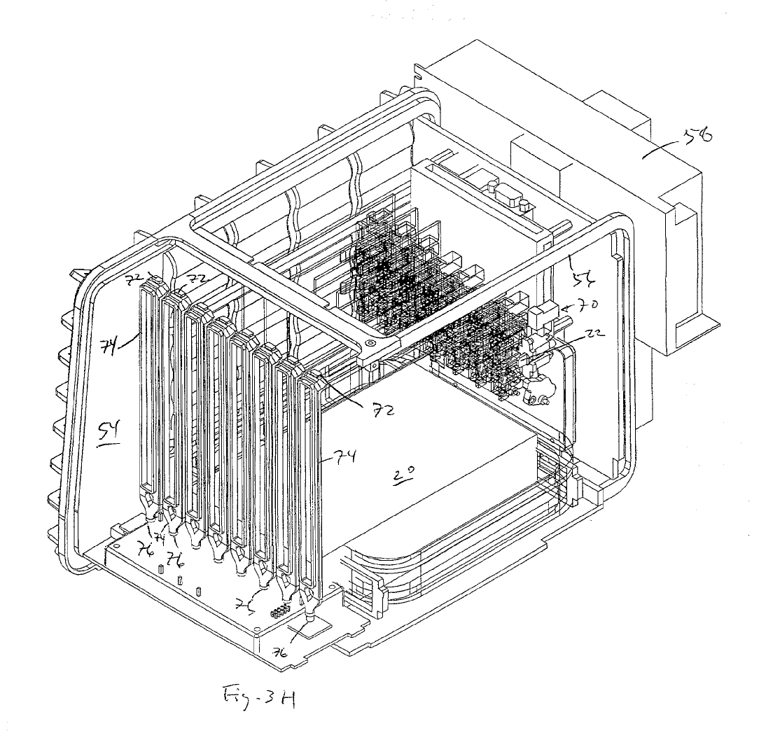

FIG. 3A depicts system 10 with panels 42, 43 removed from view. As illustrated in FIG. 3A, a plurality of batteries 44 may be supported under side panels 42 of housing 32.

A cage 46 is provided over each group of batteries 44 and provides direct support for a respective panel 42.

FIG. 3B illustrates the same features as those shown in FIG. 3A without some of the stored devices 30. Thus, FIG. 3B illustrates a fascia panel 48 residing in the storage section of housing 32. Fascia panel 48 includes a plurality of elongated slots 50. Each slot 50 is configured (sized) to receive a device 30 therein and functions to guide a device 30 received therein toward a connector 22 inside the storage section of housing 32, and also to provide at least partial support for a device 30 that is stored in the storage section of housing 32.

FIG. 3C depicts a front plan view of fascia panel 48. The connector and stop assemblies (described later) can be seen through slots 50 in this figure.

Referring now to FIG. 3D, which illustrates the same features as those in FIG. 3B without batteries 44 and cage 46, the frame elements supporting cage 46 may be elongated brackets 52 installed on the interior frame that supports panels 42, 43. The interior frame may include support plates 54 to support panels 42, and a plurality of braces 56, 56′ integrated with support plates 54 to define an interior frame. The braces include transverse brace 56′ that directly connects the top edges of support panels 54, and a plurality of preferably parallel braces 56 each including a section that is parallel to the edges of support panels 54 and directly connected to transverse brace 56′.

Note that braces 56 bend downwardly and each may include a section that functions as a support for a back panel or direct support for a packaged power converter 58 that converts AC line power to a suitable power input for the various electronic components of system 10. FIG. 3E illustrates this configuration.

FIG. 3E further illustrates one device 30 in its stored position. As can be seen, an end of device 30 is supported inside the storage section of housing 30 and the other end thereof is supported inside a respective slot 50. To properly align and assist in guiding each device 30 to a connector 22 inside the storage section, a guide plate 60 is associated with each slot 50. Each guide plate 60 is supported on a support wall 62 adjacent a connector assembly 64.

FIG. 3F is a top plan view without braces 56 illustrating guide plates 60 inside the storage section of housing 32. Each guide plate 60 is adjacent to and associated with a respective connector assembly 64, a respective stop assembly, and a respective slot 50.

Also shown in FIGS. 3E and 3F is a packaged computer 66, which is preferably stored behind connector assemblies 64 or support wall 62. Packaged computer 66 includes at least memory 18 and processor 16. In the preferred embodiment, packaged computer 66 and charging circuit assembly 14 reside on and are supported by support wall 62. Wireless router 20 resides below the storage section of housing 32 inside housing 32.

FIG. 3G illustrates system 10 as shown in FIG. 3E without guide plate 60 and device 30 to better illustrate connector assembly 64 from among the connector assemblies 64. Each connector assembly 64 includes a connector 22 and a connector support 68 on which connector 22 is supported, each connector support 68 may be supported on support wall 62. Each connector support 68 supports its associated connector 22 in a position and orientation so that the power input connector of a device 30 will receive connector 22 when device 30 is inserted in place.

Preferably, connector assembly 64 is adjacent a releasable stop assembly 70. Each releasable stop assembly 70 includes a movable stop. When the stop of a releasable stop assembly 70 is pushed toward support wall 62 by a device 30 that is in the process of being stored, the stop locks at a predesignated stop position to stop device 30 from further advancement into the storage section. The stop position of the stop is selected to ensure proper engagement of its associated connector 22 with the power input receptacle of device 30.

Each releasable assembly 70 is preferably configured to release the stop when pushed toward support wall 62 a second time by the stored device 30. The stop is preferably spring-loaded so that upon being released it pushes the stored device 30, with which it is in contact in its engaged state, away from support wall 62. Alternatively, the stop may be magnetically coupled so that it may be releasable.

Optionally, a clamp or the like device may be associated with the releasable stop 70 to prevent a stored device 30 from being withdrawn unless stored device 30 is first pushed toward support wall 62 to disengage the clamp. Thus, in this optional configuration, the clamp engages the stored device 30 once the stop reaches its stop position for additional security. Preferably, the stop and the clamp assemblies are based on a push-push mechanism usually employed in automotive applications.

Preferably, each slot 50 is adjacent a respective visual indicator 72. Once a device 30 is properly received in its stored position and properly connected to a connector 22 associated with said slot 50, the associated visual indicator is operated to inform the user of a successful connection.

Referring to FIG. 3H, which illustrates the features shown in FIG. 3G without fascia plate 48, each visual indicator 72 is integrated with a light pipe 74 and is exposed through a respective opening in fascia plate 48 above a respective slot 50. Each light pipe 74 may be an elongated body having an opening that registers with a slot 50, and an end portion aligned with a light source 76, which may be an LED, that is operated once a device 30 is successfully received and properly connected to a connector. A single circuit board may support all light sources 76.

FIGS. 3A-3H illustrate the arrangement of components inside housing 32 of system 10 from the left side thereof. It should be noted that the right side view would be identical, and, for the sake of brevity it is not illustrated.

A suitable application for a system 10 according to the present invention is a combination server and recharging station for an in-flight entertainment system. Such a system 10 may be configured to be compact enough to fit behind a seat on a plane and receive power from an outlet provided in the plane.

System 10 may be loaded with movies or other media that can be streamed to wireless devices 30 on demand over the built in wireless network. System 10 can also be connected to outside information sources such as the World Wide Web via an Internet connection, a camera that provides images from outside of the plane while in flight, or a source of avionics data. Information from the external information sources may be then shared with the passengers via router 20.

A system 10 according to the present invention may also be configured to serve as a USB hub allowing synchronization to computing devices 30 (e.g. iPads) without removing them from system 10.

According to one embodiment, system 10 is configured to allow reception of a device 30 in one orientation, thus ensuring that device 30 is properly aligned with a connector 22.

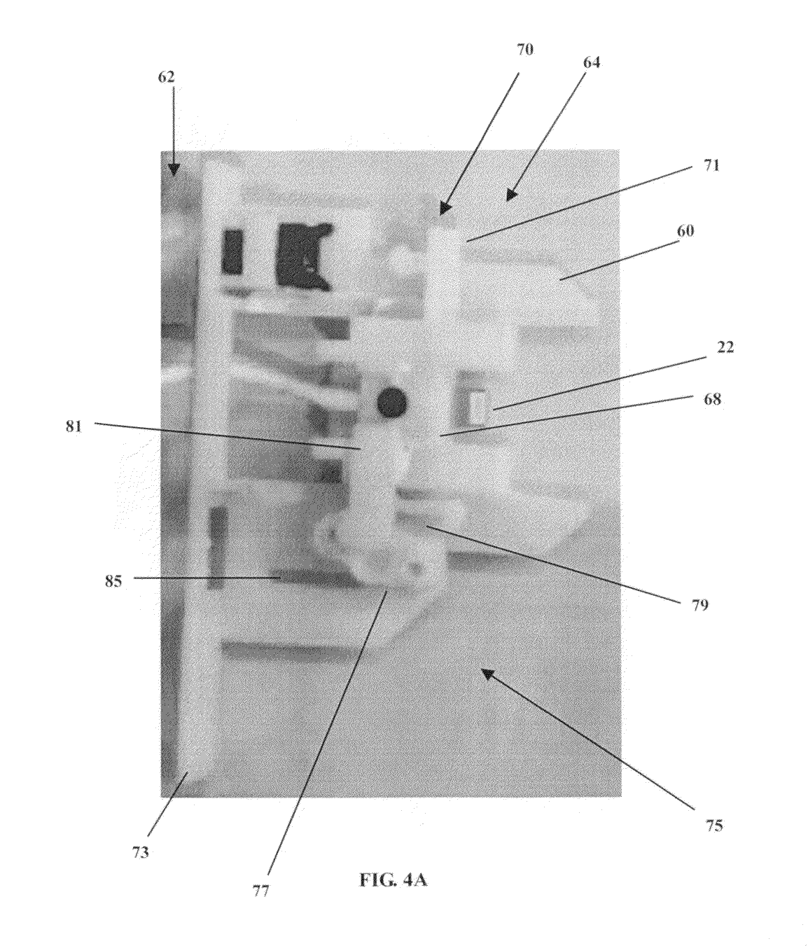

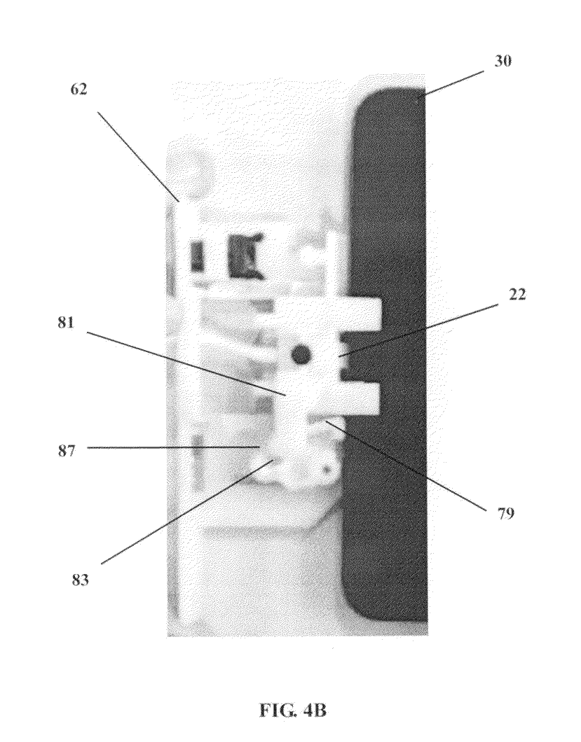

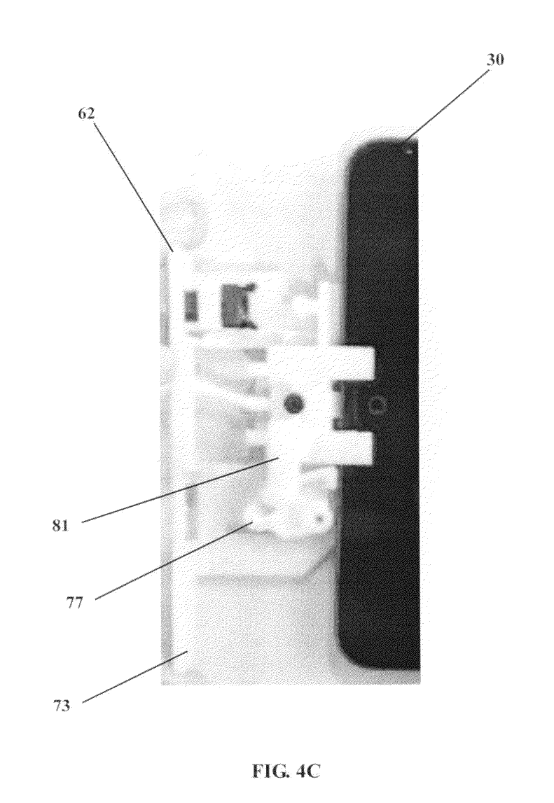

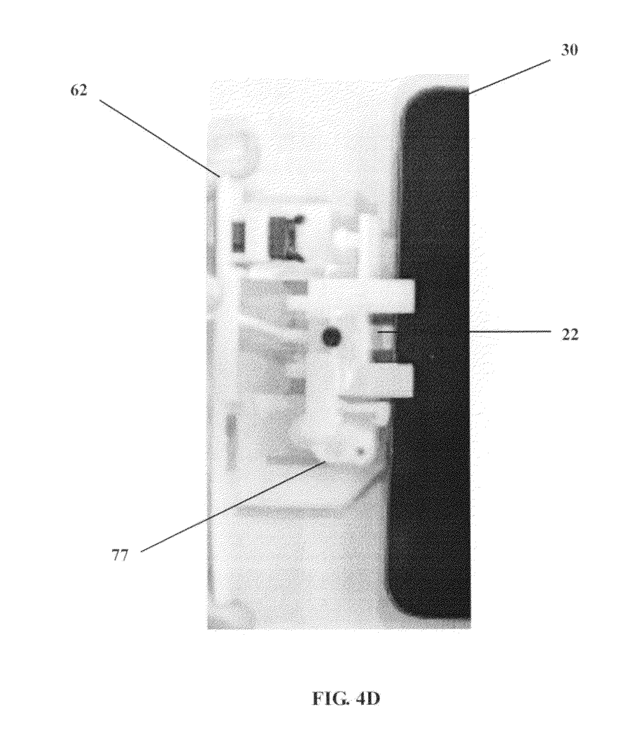

FIG. 4A shows a connector assembly 64 for use with a preferred embodiment of system 10. Connector assembly 64 includes a stop 71, which is slidably mounted on a support bracket 73. Support bracket 73 may be mounted on wall 62 (the position of wall 62 is illustrated by an arrow), thus allowing stop 71 to slidably move toward and away from wall 62. A connector 22 is mounted into stop 71 to be received inside a receptacle of a device 30. In a first state, stop 71 is at its farthest position from wall 62 and ready to be received in a receptacle associated with a device 30.

To prevent stop 71 from moving toward wall 62, a releasable lock assembly 75 is associated with stop assembly 70. Releasable lock assembly 75 includes a rotatable catch 77, which is rotatably mounted on support bracket 73. Rotatable catch 77 includes a blind slot 79, which receives a latch 81 mounted on stop assembly 70. Latch 81 abuts the blind end 83 of slot 79, which prevents stop assembly 70 from moving toward wall 62. Once catch 77 is rotated so that blind end 83 of slot 79 no longer abuts latch 81, then stop assembly 70 is allowed to move toward wall 62.

Specifically, a groove 87 (see FIG. 4B) is provided adjacent blind end 83 of slot 79. Once groove 87 is aligned with latch 81 then latch 81 is allowed to leave slot 79 and move toward wall 62 unimpeded by catch 77. Thus, unless catch 77 is rotated until it is disengaged, latch 81 cannot move toward wall 62, thereby preventing stop assembly 70 from moving toward wall 62. It should be noted that catch 77 is configured to slidably move toward wall 62. Thus, for example, a guide slot 85 may be defined in a portion of support 73 to guide catch 77 toward wall 62 after it is disengaged. Catch 77 is preferably rotatably mounted in guide slot 85.

The lock assembly 75 prevents the mis-mounting of a device 30 as follows.

Referring to FIG. 4B, which shows a connector 22 partially received in a receptacle associated with a device 30, when connector 22 is properly aligned and received in a receptacle, the body of device 30 engages (abuts) catch 77 causing catch 77 to rotate. As is clear in the figure, latch 81 no longer abuts blind end 83 of slot 79 and is aligned with groove 87. Furthermore, rotatable catch 77 becomes disengaged and can move toward wall 62.

Referring to FIG. 4C, catch 77 abuts device 30 and moves along guide slot 85 until stop assembly 70 reaches the back of bracket 73, where it is releasably locked. When device 30 is pushed again, stop assembly 70 is released, and if spring loaded, stop assembly 70 pushes device 30 away from wall 62.

Referring now to FIG. 4D, if connector 22 is not received in a receptacle associated with a device 30, device 30 cannot advance toward wall 62. Consequently, the body of device 30 cannot effectively engage rotatable catch 77 in order to rotate the same and allow stop assembly 70 to advance toward wall 62.

A system 10 according to the present may be devised to be modular so that it may be configured to the needs of the end user. For example, the number of connectors 22 may be expanded to accommodate more wireless devices 30 of the same kind, or wireless devices of different kind may be deployed in the same system

Housing 32 may be provided with removable panels 42, 43 whereby the exterior appearance of system 10 may be changed to match the aircraft or the décor surrounding system 10.

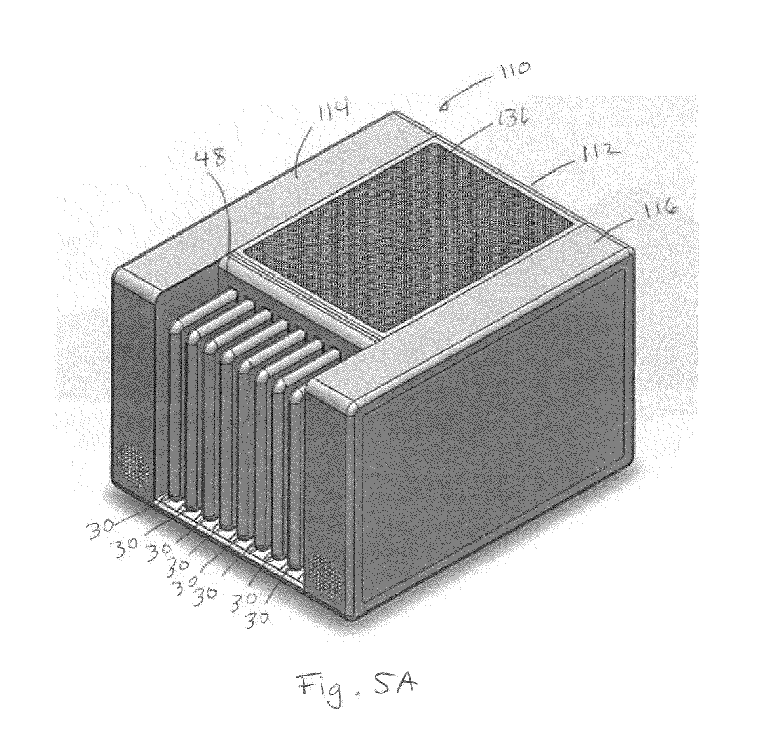

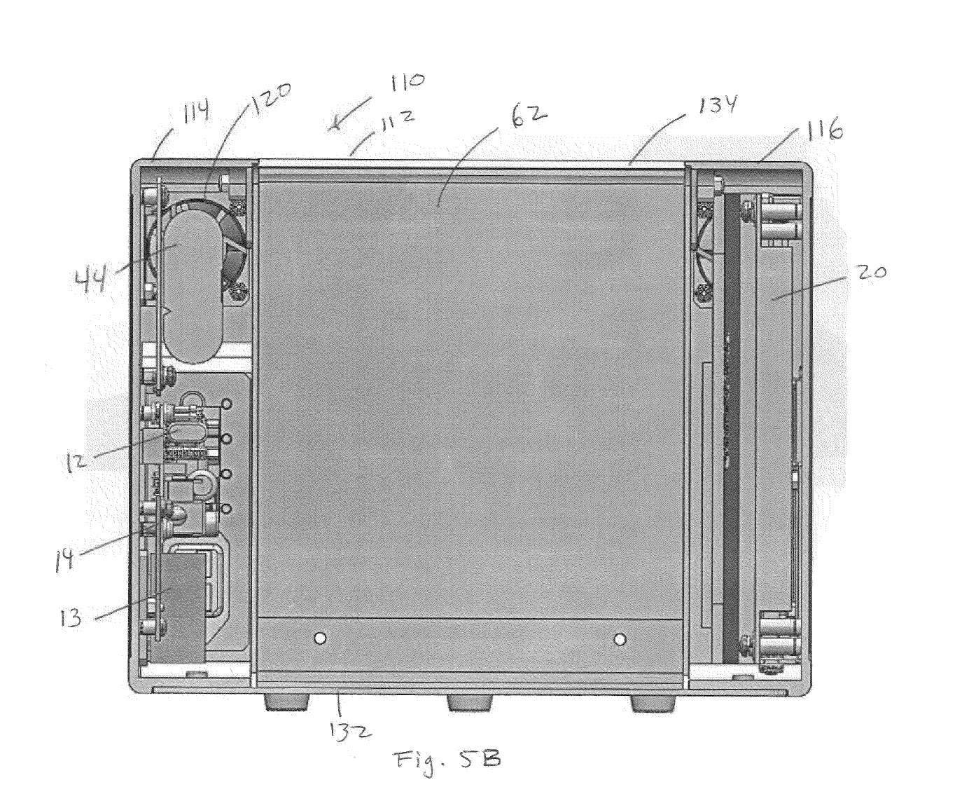

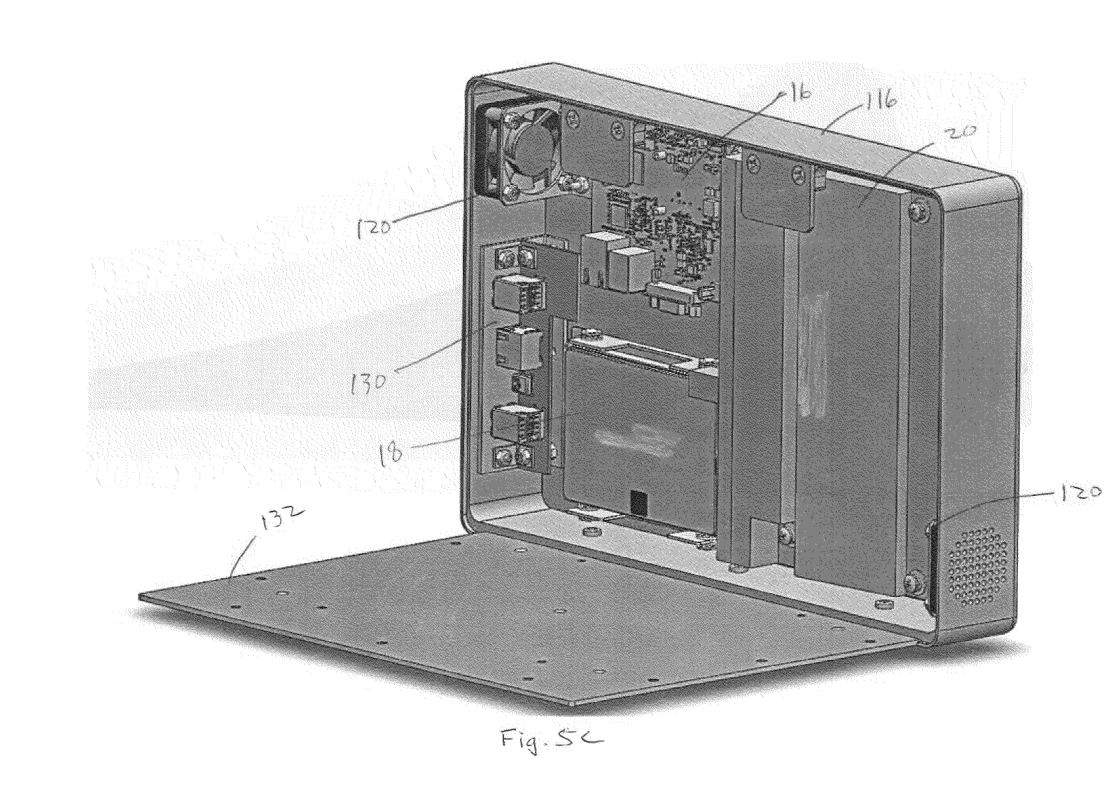

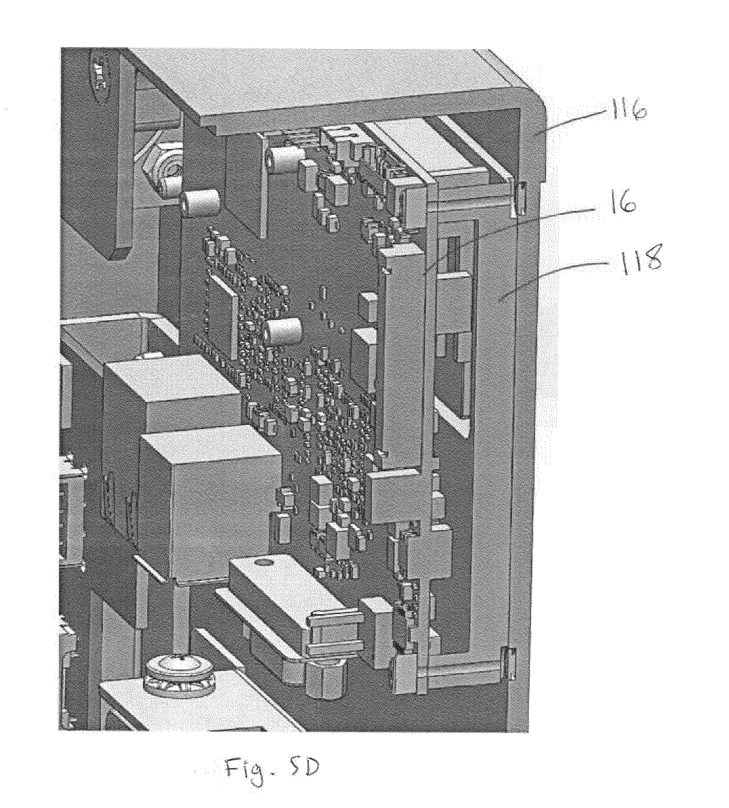

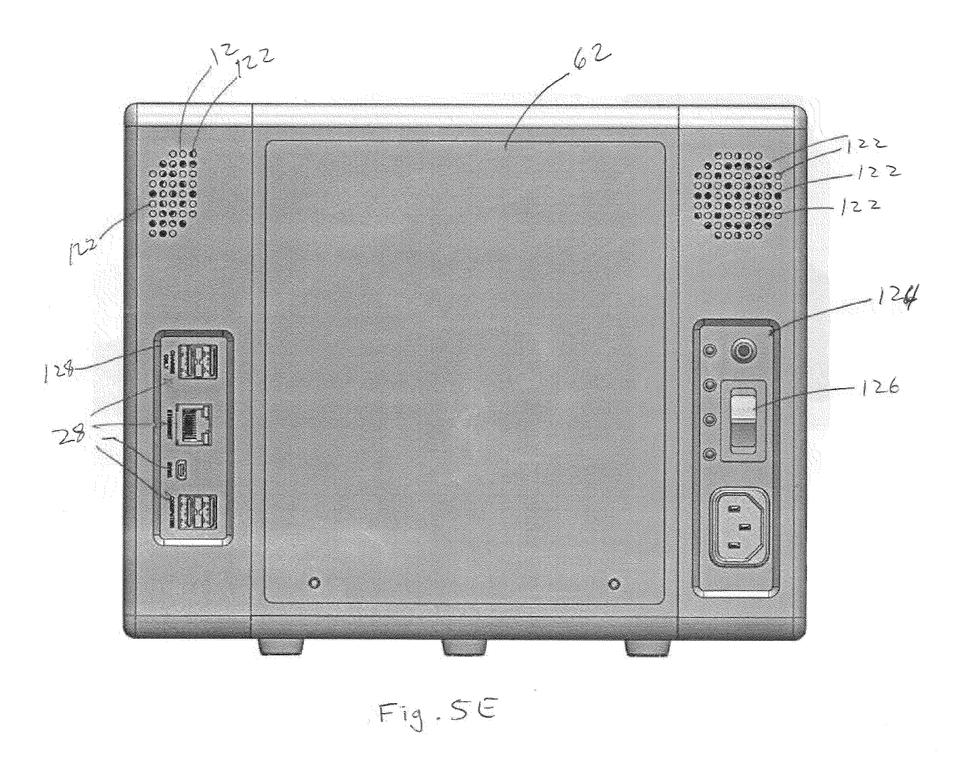

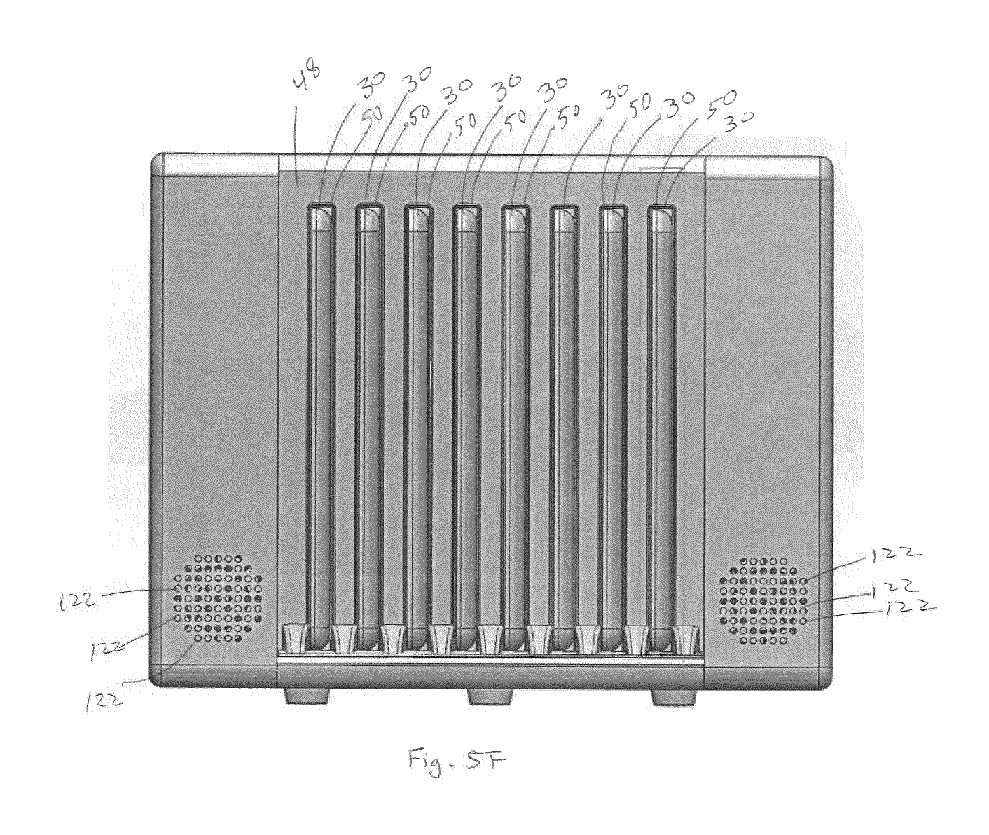

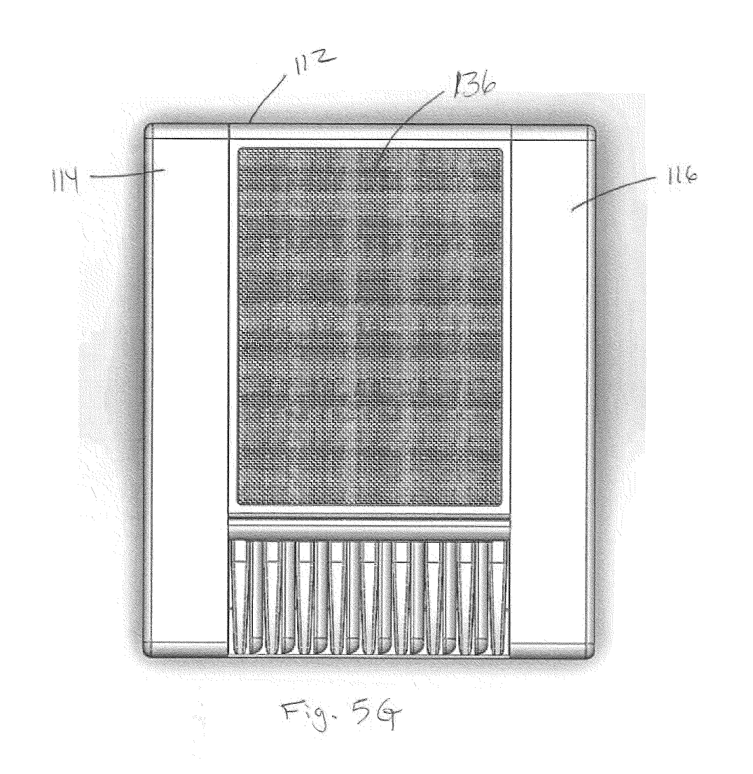

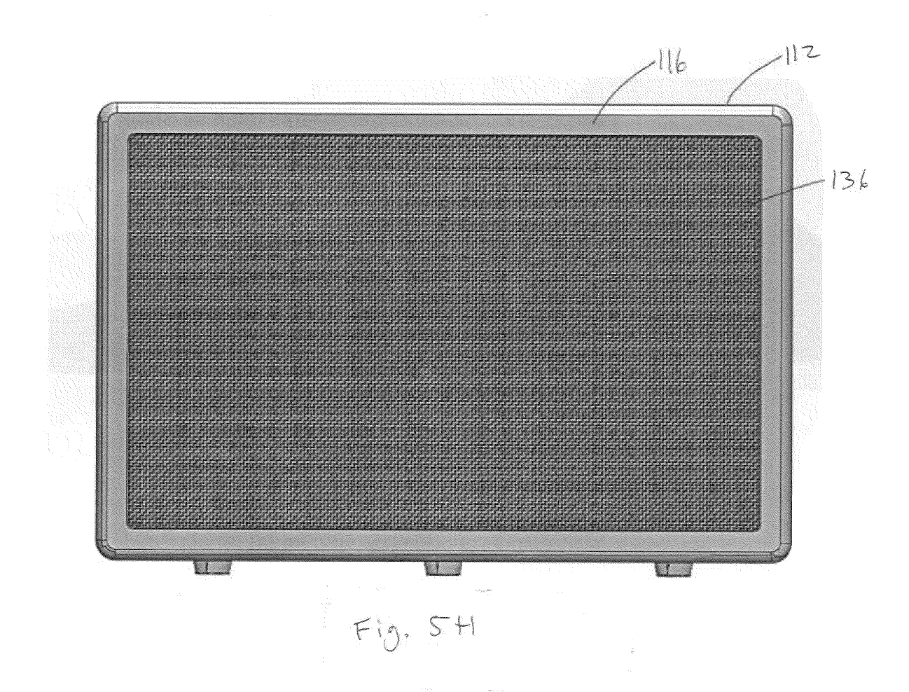

Referring to FIG. 5A, a system 110 according to the second embodiment includes a housing 112 that defines a storage section for receiving wireless devices 30 as in the first embodiment. Housing 112 includes two side trays 114,116. Each side tray 114,116 is preferably made of aluminum or the like metallic body that capable of dissipating heat. In this embodiment, the components are installed on trays 114,116. Thus, for example, power supply 12 and battery 44, charger circuit 14, and other power supplies (e.g. power supply 13 for router 20) are installed on tray 114 as shown in FIG. 5B, while processor 16, router 20, and non-volatile memory 18 (e.g. a solid state hard drive) are installed on tray 116 as shown in FIG. 5C. As illustrated in FIG. 5D, a heatsink 118 may be used to thermally couple processor 16 to tray 116, whereby tray 116 is used as a heat spreader. Any other heat generating component in the system may be mounted in the same manner as processor 16 in order to use trays 114, 116 as heat spreaders to effectively dissipate the heat.

Each tray 114,116 may include a plurality of vent holes 122 (see FIGS. 5E and 5F). A fan 120 or the like may be installed inside each tray in association with a group of vent holes 122 in order to push out hot air from within housing 112. As shown in FIGS. 5E and 5F further illustrate the location of vent holes 122. Referring to FIG. 5E, each tray 114, 116 may further include an opening spaced from vent holes 122 through which connection can be made to internal components. For example, an opening 124 allows connection to the power supply 12 through a power receptacle. Also, an on/off button 126 may be provided here to turn the system on or off. Through, an opening 128 input/output ports 28 may be accessed. Thus, for example, USB ports or ethernet ports may be accessed through opening 128. These ports may reside on a board 130 that is installed behind opening 128 as illustrated by FIG. 5C.

To realize housing 112, trays 114,116 are connected to one another by a base panel 132 (see FIGS. 5B and 5C) and top panel 134. A back support wall 62 and fascia panel 48 can then complete the housing. The connector assemblies and the remaining components for receipt and retention of devices 30 can be the same as those in the first embodiment.

In the second embodiment, the internal framework can be omitted in order to increase the interior space and allow for better flow of air inside the housing to keep the components cool.

Decorative trim 136 or the like may be installed on the exterior surfaces of, for example, top panel 132 (See FIG. 5H) or trays 114,116 (see FIG. 5I) to change the appearance of the housing and/or hide screws used for the assembly of housing 112.

As mentioned earlier a system according to the present invention is particularly suited for use on an aircraft. The system's portability allows it to be easily moved between aircrafts. The system is easier and cheaper to install and not subject to as many regulatory requirements. Furthermore, the system can be more easily and cheaply updated if necessary while an installed systems for an aircraft will have to adhere to original specifications as they were certified.

A system according to the present invention is best suited for environments that lack easy and inexpensive internet access such as an aircraft or a boat. In an aircraft, internet access is very expensive both for the hardware and usage. An installed (non-portable) system that can provide the functionality of a system according to the present invention can easily cost over $250,000 to install, and its usage can cost tens of thousands of dollars in just one flight.

In addition, there are few if any airborne systems that have the bandwidth that would allow multiple users to stream media like movies. By keeping this media on the aircraft itself and avoiding the requirement for internet streaming, a system according to the present invention allows more users to enjoy the media that would otherwise be possible with a conventional, installed system, while lowering the costs.

By keeping the media on the system, it is not necessary to have each computing device loaded with up to date content. In addition using a central server allows for more storage capacity that would normally be available on computing devices 30 (e.g. iPads). The system also saves costs by avoiding the expense of increasing the storage capacity of individual computing devices. Rather, the non-volatile memory could be replaced with another memory of larger capacity, another non-volatile memory could be added, or an external non-volatile memory (another hard drive) could be simply connected to the system via one of the Input/Output ports.

While the embodiments shown herein include one battery, a plurality of batteries may be provided, each, for example, providing charge for a respective computing device.

The system, in its preferred form for use on an aircraft, may be 10.5×12.25×7.5 inches and about 15-25 pounds. The dimensions of the system are selected so that it may fit behind a seat in an aircraft or under a seat in an aircraft. Thus, the dimensions and the weight may be varied as long as the system remains suitable for portability (can be carried by a person) and used on an aircraft.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

1. A system comprising:
a portable housing defining a section for receiving a plurality of computing devices and having housed therein a plurality of components that are configured to provide power and information to said computing devices, said components including at least a power supply, a processor, and a router, wherein air in said section for receiving said plurality of computing device can circulate among said components residing in said portable housing.

2. The system of claim 1, wherein said housing includes a fascia panel having a plurality of elongated slots each configured to receive a respective computing device and to guide said computing device so received into said section for receiving said plurality of computing devices, said fascia panel being positioned opposite a support wall that supports a plurality of connectors, each connector being configured for connection to a respective computing device.

3. The system of claim 2, wherein said housing includes an internal open frame work supporting a plurality of panels that define said portable housing.

4. The system of claim 2, wherein each connector is mounted on said support wall with a respective connector support, which connector support positions and orients its associated connector for connection to a power input connector of a respective computing device.

5. The system of claim 2, wherein each connector is associated with a connector assembly and each connector assembly is associated with a respective releasable stop assembly, each releasable stop assembly including a movable stop which when pushed toward said support wall by a computing device will move until reaching a stop position to prevent further advancement of said computing device.

6. The system of claim 5, wherein each releasable stop assembly is configured to release said stop when said stop is pushed toward said support wall after it has been locked.

7. The system of claim 6, wherein each said stop is spring loaded.

8. The system of claim 5, wherein each said stop is associated with a respective lock assembly, each said lock assembly including a rotatable catch that cooperates with a latch to prevent said stop from moving toward said support wall.

9. The system of claim 8, wherein each said lock assembly prevents mismounting of a computing device.

10. The system of claim 2, wherein each slot in said fascia plate is associated with a visual indicator.

11. The system of claim 2, wherein said housing includes a plurality of metallic trays that support said components.

12. The system of claim 11, wherein one of said trays supports said power supply, and another one of said trays supports said router and said processor.

13. The system of claim 12, further comprising groups of vent holes defined in each said tray, and a fan associated with each group of vent holes.

14. The system of claim 1, wherein said components further include a charger circuit, a non-volatile memory, input/output connectors, and at least one rechargeable battery.

15. A system comprising:
a portable housing having at least one metallic tray, the portable housing having housed therein a plurality of components that are configured to provide power and information to a plurality of computing devices, said components including at least a power supply, a processor, and a router, wherein at least one of said components is thermally coupled to said metallic tray.

16. The system of claim 15, wherein said housing includes a fascia panel having a plurality of elongated slots each configured to receive a respective computing device and to guide said computing device so received into a section for receiving said plurality of computing devices inside said housing, said fascia panel being positioned opposite a support wall that supports a plurality of connectors, each connector being configured for connection to a respective computing device.

17. The system of claim 16, further comprising another metallic tray arranged opposite said metallic tray, wherein at least another one of said components is coupled to said another metallic tray, and wherein said metallic tray and said another metallic tray are arranged on opposite sides of said section for receiving said computing devices.

18. The system of claim 15, wherein said metallic tray includes a plurality of vent holes allowing air to pass from interior of said housing to exterior of said housing.

19. The system of claim 18, further comprising an electric fan installed adjacent said vent holes.

20. The system of claim 15, wherein said metallic tray is comprised of aluminum.
